(19) United States
(12) Patent Application Publication
(10) Pub. No.: US 2013/0102123 A1
(43) Pub. Date: Apr. 25, 2013

(54) METHOD FOR FABRICATING SINGLE-SIDED BURIED STRAP IN A SEMICONDUCTOR DEVICE

(71) Applicants: Tzu-Ching Tsai, Taoyuan County (TW); Yi-Nan Chen, Taoyuan County (TW); Hsien-Wen Liu, Taoyuan County (TW)

(72) Inventors: Tzu-Ching Tsai, Taoyuan County (TW); Yi-Nan Chen, Taoyuan County (TW); Hsien-Wen Liu, Taoyuan County (TW)

(73) Assignee: NANYA TECHNOLOGY CORPORATION, TAOYUAN (TW)

(21) Appl. No.: 13/276,960

(22) Filed: Oct. 19, 2011

(51) Int. Cl. H01L 21/02

(52) U.S. Cl. 438/386; 257/E21.008

(57) ABSTRACT

A method for manufacturing a buried-strap includes: forming a trench capacitor structure in a semiconductor substrate, wherein the trench capacitor structure has a doped polysilicon layer and an isolation collar covered by the doped polysilicon layer, and a top surface of the doped polysilicon layer is lower than a top surface of the semiconductor substrate such that a first recess is formed; sequentially forming a first resist layer, a second resist layer and a third resist layer over the semiconductor substrate; sequentially patterning the third resist layer, the second resist layer and the first resist layer, forming a patterned tri-layer resist layer over the semiconductor substrate; partially removing a portion of the doped polysilicon layer exposed by the patterned tri-layer resist layer to form a second recess; removing the patterned tri-layer resist layer; and forming an insulating layer in the second recess and a portion of the first recess.

### BACKGROUND OF THE INVENTION

1. Field of the Invention

The present invention generally relates to a method for manufacturing semiconductor devices, and more particularly to a method for manufacturing a single-sided buried strap in a semiconductor device.

2. Description of the Related Art

Dynamic random-access memory (DRAM) cells are composed of two main components, a storage capacitor that is used to store electronic charges and an access transistor that is used to transfer the electronic charges to and from the storage capacitor. The storage capacitor may be either planar on the surface of the semiconductor substrate or trench etched into the semiconductor substrate. In the semiconductor industry where there is an increased demand for memory storage capacity accompanied with an ever decreasing chip size, the trench storage capacitor layout is favored over the planar storage capacitor design because this particular setup results in a dramatic reduction in the space required for the capacitor without sacrificing capacitance.

A very important and extremely delicate element in the DRAM cell is the electrical connections made between the trench storage capacitor and the access transistor. Such a contact is often referred to in the art as a buried strap formed at the intersection of one electrode of the storage trench capacitor and one source/drain junction of the access transistor.

Referring to FIGS. 1A to 1C, a conventional method for manufacturing a buried-strap at the intersection of the trench storage capacitor and the access transistor is schematically illustrated. By the masking of a patterned pad layer 102, a trench 104 is formed into a semiconductor substrate 100 using well known dry etching techniques. An isolation collar 106 is formed on lower sidewalls of the trench 104 as shown in FIG. 1A. A doped polysilicon layer 108 is sequentially filled into the lower portion of the trench 104, which is followed by conformal formation of a silicon nitride layer 110 and an amorphous silicon layer 112. By a tilt angle, impurities 114 are implanted into a portion of the amorphous silicon layer 112.

On account of etch selectivity between impurity-containing and undoped portions of the amorphous silicon layer, the impurity-containing portion of the amorphous silicon layer 112 remains after an wet-etching process (not shown) is applied to remove the undoped portion of the amorphous silicon layer 112 as shown in FIG. 1B. Then, the silicon nitride layer 110 is patterned by a wet-etching process (not shown) by using the impurity-containing portion of the amorphous silicon layer 112 as a masking film, wherein portions of the silicon nitride layer 110 covered by the impurity-containing portion of the amorphous silicon layer 112 remain over the doped polysilicon layer 108. The doped polysilicon layer 108 is then patterned using the impurity-containing portion of the amorphous silicon layer 112 and the patterned silicon nitride layer 110 as a masking film such that a recess 116 is formed in the doped polysilicon layer 108, exposing a portion of the isolation collar 106.

In FIG. 1C, an insulating layer 118 is formed on a portion of the upper sidewalls of the trench 104, using known deposition and etching processes, to fill the recess 116. The amorphous silicon layer 112 and the silicon nitride layer 110 are thereafter removed such that a buried strap 120 is formed.

However, the process steps of the method for manufacturing the buried-strap at the intersection of the trench storage capacitor and the access transistor as shown in FIGS. 1A-1C are complex and time-consuming such that an easier and more time-effective method for manufacturing a buried-strap in semiconductor devices is desired.

### BRIEF SUMMARY OF THE INVENTION

A method for manufacturing a buried-strap in a semiconductor device comprises: forming a trench capacitor structure in a semiconductor substrate, wherein the trench capacitor structure has a doped polysilicon layer and an isolation collar covered by the doped polysilicon layer, and a top surface of the doped polysilicon layer is lower than a top surface of the semiconductor substrate such that a first recess is formed; sequentially forming a first resist layer, a second resist layer and a third resist layer over the semiconductor substrate, wherein the first resist layer fills the recess of the trench capacitor structure and the first, second and third resist layers have planar surfaces; sequentially patterning the third resist layer, the second resist layer and the first resist layer, forming a patterned tri-layer resist layer over the semiconductor substrate, wherein the patterned tri-layer resist layer partially exposed a portion of the top surface of the doped polysilicon layer and the first recess; partially removing a portion of the doped polysilicon layer exposed by the patterned tri-layer resist layer to form a second recess, wherein the second recess exposes a portion of the isolation collar; removing the patterned tri-layer resist layer; and forming an insulating layer in the second recess and a portion of the first recess, covering the portion the isolation collar exposed by the second recess.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIGS. 1A-1C are cross-sectional views of process steps for a conventional method for manufacturing a single-sided buried strap; and

FIGS. 2A-2F are cross-sectional views of process steps in a method for manufacturing a single-sided buried strap according to an embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

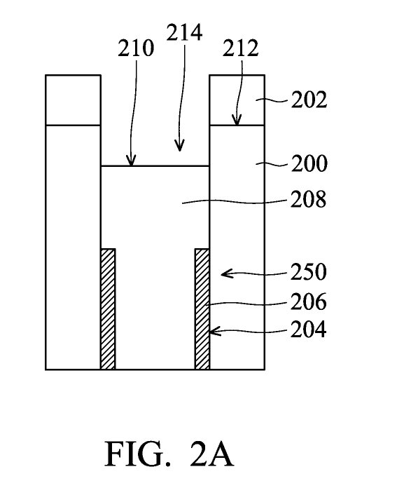

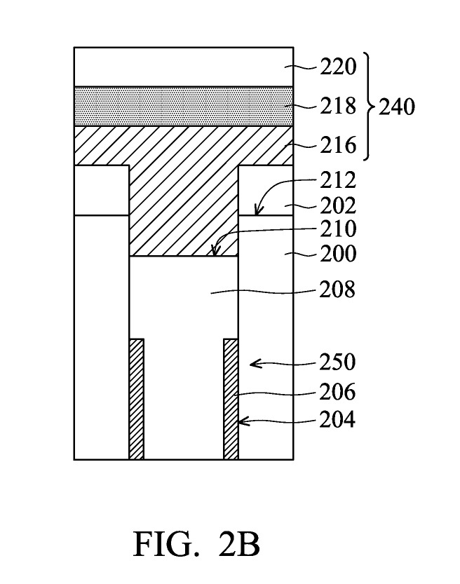

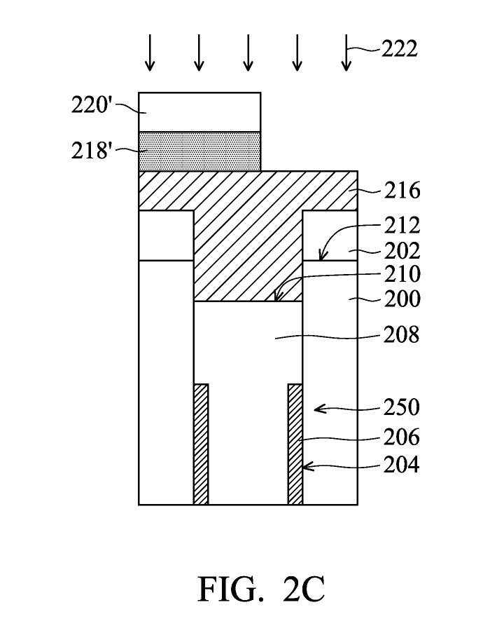

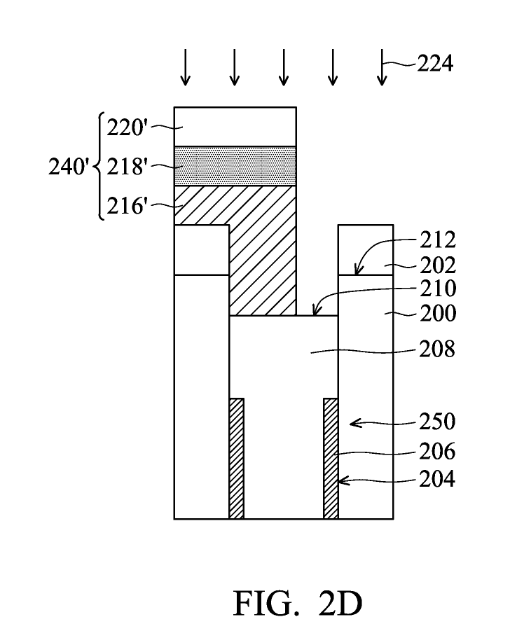

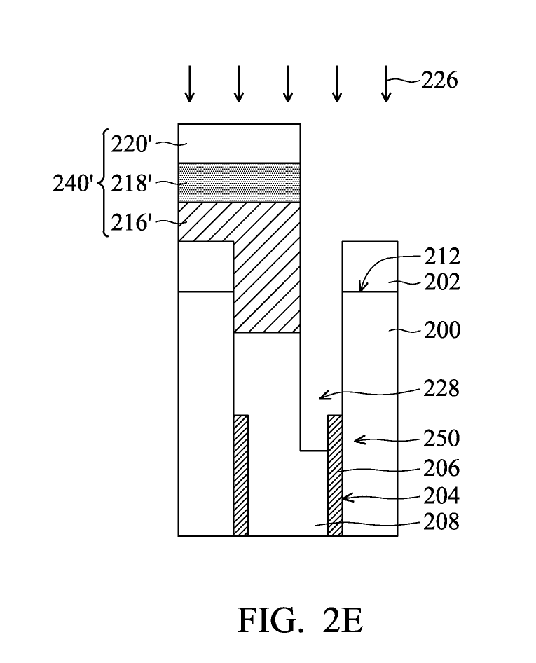

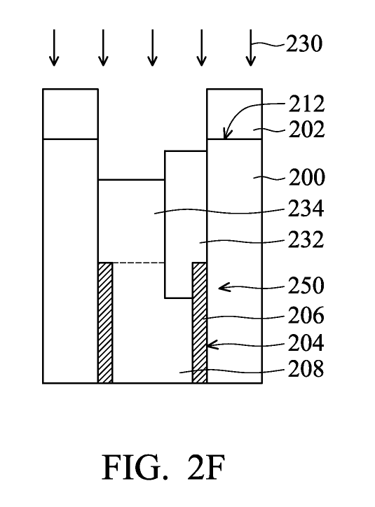

Referring to FIGS. 2A-2F, cross-sectional views of the process steps in an exemplary method for manufacturing a single-sided buried strap are illustrated. In FIG. 2A, a trench capacitor structure 250 is provided in a semiconductor substrate 200 such as a silicon substrate; however, portions of the trench capacitor structure 250 are not shown for the purpose of simplicity. The trench capacitor structure 250 comprises a trench 204 formed into the semiconductor substrate 200, an isolation collar 206 formed on lower sidewalls of the trench 204, and a doped polysilicon layer 208 filled in a portion of the trench 204 to cover the isolation collar 206. The trench 204 is formed by using known dry etch techniques, using a patterned pad layer 202 as a hard mask. Thus, the trench capacitor structure 250 is provided with a surface 210 lower than the surface 212 of the semiconductor substrate 200 such that a recess 214 is left in the trench 204, as shown in FIG. 2A.

In FIG. 2B, a first resist layer 216 is blanketly formed over the semiconductor substrate 200, covering the patterned pad layer 202 and fills the recess 214 formed in the trench 204. The first resist layer 216 comprises materials such as i-line resists and may be formed by a spin-on method, thereby having a planar top surface. Next, a second resist layer 218 is blanketly formed over the first resist layer 216. The second resist layer 218 comprises materials different from that of the first resist layer 216, such as silicon-containing resists, and may be formed by a spin-on method, thereby having a planar top surface. Next, a third resist layer 220 is blanketly formed over the second resist layer 218. The third resist layer 220 comprises materials different from that of the second resist layer 218 and the first resist layer 216, such as ArF resists and can be formed by, for example, a spin-on method, thereby having a planar top surface. The first resist layer 216, the second resist layer 218 and the third resist layer 220 forms a tri-layered resist 240 for forming a buried strap in a semiconductor device.

In FIG. 2C, a photolithography process and a sequential development process (both not shown) are performed to the third resist layer 220, thereby leaving a patterned third resist layer 220′ over the second resist layer. Next, an etching process 222 is performed to etch the second resist layer 218, using the patterned third resist layer 220′ as an etching mask, thereby leaving a patterned second resist layer 218′ over the first resist layer. The etching process 222 can be, for example, a dry etching process using adequate gaseous etchants. On account of significant etch selectivity between the resist materials of the second resist layer 218 and the first resist layer 216, the second resist layer 218 can be patterned in the etching process 222 and the first resist layer 216 remains unetched in the etching process 222. The patterned second resist layer 218′ is formed with a configuration that is the same as that of the patterned third resist layer 220′. As shown in FIG. 2C, the patterned third resist layer 220′ and the patterned second resist layer 218′ partially overlaps a top surface of the trench capacitor structure 250 and a portion of the first resist layer 216 above the trench capacitor structure 250 is thus exposed.

In FIG. 2D, an etching process 224 is performed to etch the portion of the first resist layer 216 exposed by the patterned second resist layer 218′ and the patterned third resist layer 220′, using the patterned second resist layer 218′ and the patterned third resist layer 220′ as etching masks, thereby forming a patterned first resist layer 216′ over the semiconductor substrate 200, partially filling the recess 214 and covering the patterned pad layer 202 adjacent to a side of the recess 214. The patterned first resist layer 216′, the patterned second resist layer 218′ and the patterned third resist layer 220′ form a tri-layer patterned resist layer 240′ for forming a buried strap in a semiconductor device. The etching process 224 can be, for example, a dry etching process using adequate gaseous etchants. On account of significant etch selectivity between the resist materials of the first resist layer 216 and the doped polysilicon layer 208, the first resist layer 216 can be patterned in the etching process 224 and the doped polysilicon layer 208 remains unetched in the etching process 224. The patterned first resist layer 216′ is formed with a configuration that is the same as that of the patterned second resist layer 218′ and the patterned third resist layer 220′. After the etching process 224, a portion of a top surface of the doped polysilicon layer 208 is exposed by the patterned first resist layer 216′, the patterned second resist layer 218′ and the patterned third resist layer 220′.

In FIG. 2E, an etching process 226 is performed to etch the doped polysilicon layer 208 exposed by the tri-layer patterned resist layer 240′, thereby forming a recess 228 in the doped polysilicon layer 208. The recess 228 exposes a portion of the isolation collar 206 at a side of the trench 204. The etching process 226 can be, for example, a dry etching process using adequate gaseous etchants.

In FIG. 2F, an ashing process 230 such as a plasma ashing process is performed to entirely remove the patterned tri-layer resist layer 240′ from the semiconductor substrate 200, thereby leaving the doped polysilicon layer 208 with the recess 228 therein. Next, an insulating layer 232 is formed on a portion of the upper sidewalls of the trench 204 and fills the recess 228 using known deposition and etching processes such that a buried strap 234 is formed in the trench 204.

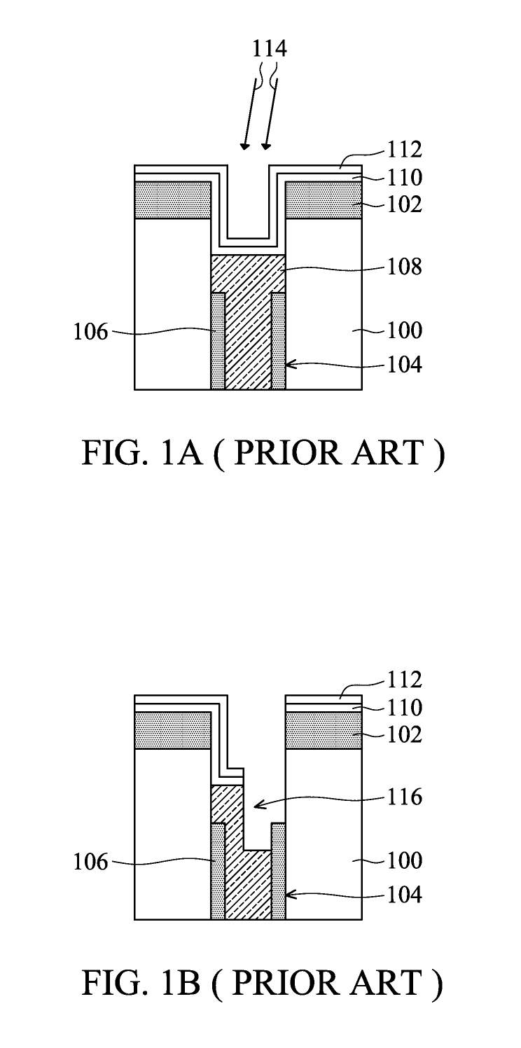

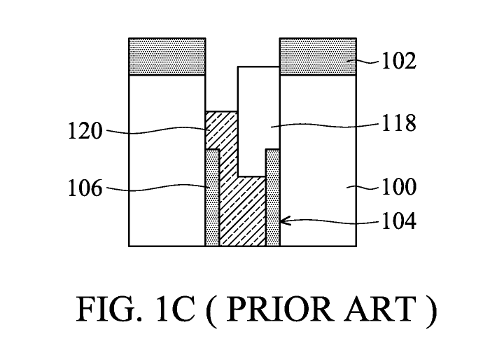

In one embodiment, formation of the first resist layer 216, the second resist layer 218 and the third layer 220 shown in FIG. 2B can be sequentially formed by the same coater (not shown) having multiple resist storage tanks which respectively contains a material for forming thereof, and the etching processes 222 and 224, and the ashing process 230 can be sequentially performed in a compact etching apparatus (not shown) having multiple etching chambers capable of performing the above etching and ashing processes. The exemplary method for manufacturing a single-sided buried strap in a semiconductor devices illustrated in FIGS. 2A-2F thus shows an easier and more time-effective method when compared with the conventional method for manufacturing a single-sided buried-strap in semiconductor devices shown in FIGS. 1A-1C because time-consuming processes such as film depositions, wet-etching, and impurities implantation are no more needed.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for manufacturing a single-ended buried strap, comprising:
forming a trench capacitor structure in a semiconductor substrate, wherein the trench capacitor structure has a doped polysilicon layer and an isolation collar covered by the doped polysilicon layer, and a top surface of the doped polysilicon layer is lower than a top surface of the semiconductor substrate such that a first recess is formed;
sequentially forming a first resist layer, a second resist layer and a third resist layer over the semiconductor substrate, wherein the first resist layer fills the recess of the trench capacitor structure and the first, second and third resist layers have planar surfaces;
sequentially patterning the third resist layer, the second resist layer and the first resist layer, forming a patterned tri-layer resist layer over the semiconductor substrate, wherein the patterned tri-layer resist layer partially exposed a portion of the top surface of the doped polysilicon layer and the first recess;
partially removing a portion of the doped polysilicon layer exposed by the patterned tri-layer resist layer to form a second recess, wherein the second recess exposes a portion of the isolation collar;
removing the patterned tri-layer resist layer; and
forming an insulating layer in the second recess and a portion of the first recess, covering the portion the isolation collar exposed by the second recess.

2. The method as claimed in claim 1, wherein the first resist layer comprises I-line resists.

3. The method as claimed in claim 1, wherein the second resist layer comprises silicon-containing resists.

4. The method as claimed in claim 1, wherein the third resist comprises ArF resists.

5. The method as claimed in claim 1, wherein the first, second and third resist layers are formed by a spin-on method.

6. The method as claimed in claim 5, wherein the first, second and third resist layers are formed by only one coater.

7. The method as claimed in claim 1, wherein patterning the third resist layer, the second resist layer and the first resist layer comprises:
patterning the third resist layer, forming a patterned third resist layer, wherein the patterned resist layer partially overlaps the top surface of the doped polysilicon layer and exposes portions of the second resist layer;
performing a first etching to the portions of the second resist layer exposed by the patterned third resist layer, forming a patterned second resist layer and exposing portions of the first resist layer; and
performing a second etching to the portions of the first resist layer exposed by the patterned second resist layer, forming a patterned third resist layer and exposing portions of the doped polysilicon layer and the recess, wherein the patterned first, second and third resist layers form the patterned tri-layer resist layer.

8. The method as claimed in claim 7, wherein the first resist layer is patterned by a photolithography process and a development process.

9. The method as claimed in claim 7, wherein the first and second etchings are dry etching.

10. The method as claimed in claim 7, wherein the first and second etchings are performed by the same etching apparatus.

11. The method as claimed in claim 7, wherein the portion of the doped polysilicon layer adjacent to the insulating layer and above the isolation collar functions as the buried strap.
